(19) United States
(12) Patent Application Publication
(10) Pub. No.: US 2017/0164475 A1
(43) Pub. Date: Jun. 8, 2017

(54) Printed Circuit Board Having Longitudinally Tolerant Component Vias

(71) Applicant: Delphi Technologies, Inc., Troy, MI (US)

(72) Inventors: Mark Wayne Smith, El Paso, TX (US); Jesus R. Morales, Cd. Juarez (MX)

(21) Appl. No.: 14/960,584

(22) Filed: Dec. 7, 2015

(51) Int. Cl. H05K 1/11; H05K 1/02

(52) U.S. Cl. CPC H05K 1/115; H05K 1/0298; H05K 2201/09854; H05K 2201/10257

(57) ABSTRACT

A PCB assembly includes a circuit board substrate defining a plurality of vias that are aligned along a common axis. A first via of the plurality of vias defines a circular shape and a second via defines an elongate oval shape along the common axis. The PCB assembly also includes an electrical component having a plurality of terminal pins aligned along the common axis. The plurality of terminal pins are received within the plurality of vias.

### TECHNICAL FIELD OF THE INVENTION

The invention relates to a printed circuit board, particularly a printed circuit board having longitudinally tolerant component vias.

### BACKGROUND OF THE INVENTION

Printed circuit board (PCB) assemblies often include electrical components having multiple terminal pins aligned along a common axis that are attached to the PCB, e.g. male blade terminals or TO-220 transistors. As shown in the example of FIG. 1, a male blade terminal 12 has terminal pins 14 are received in holes 16 that are drilled in the PCB 18 and plated so that the terminal pins may be electrically and mechanically attached to the PCB 18, typically be a soldering process. As illustrated in FIGS. 2 and 3, all of these holes 16 have the same generally circular shape. The holes 16 are electroplated to provide a conductive path and are often referred to as plated through holes 16 or vias 16. As can be seen in FIG. 3, each of the terminal pins 14 are in an interference fit with each of the vias 16. The positional tolerance between the vias 16 and the terminal pins 14 can creates stresses in the PCB 18 and/or terminal pins 16 that can cause cracks in the PCB 18 or the solder joints (not shown) between the terminal pins 16 and the vias 18 during thermal cycling of the PCB assembly 10. Therefore, a PCB assembly that can alleviate stresses in the PCB substrate and terminal pins remains desired.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may also be inventions.

### BRIEF SUMMARY OF THE INVENTION

In accordance with an embodiment of the invention, a printed circuit board (PCB) configured to receive an electrical component having a plurality of terminal pins aligned along a first axis. The PCB includes a circuit board substrate that defines a plurality of vias aligned along a second axis. The plurality of vias is configured to receive the plurality of terminal pins of the electrical component. A first via of the plurality of vias defines a circular shape and a second via defines an elongate oval shape along the second axis. The first axis is correspondent with the second axis when the plurality of terminal pins are receded within the plurality of vias.

The first via of the plurality of vias may be located centrally to the second via and a third via of the plurality of vias. The third via also defines an elongate oval shape along the second axis. The second via and the third via may be equidistant from the first via. A length of the second via along the second axis may be equal to a length of the third via along the second axis.

In accordance with another embodiment, a PCB assembly is provided. The PCB assembly includes a circuit board substrate defining a plurality of vias that are aligned along a common axis. A first via of the plurality of vias defines a circular shape and a second via defines an elongate oval shape along the common axis. The PCB assembly also includes an electrical component having a plurality of terminal pins aligned along the common axis. The plurality of terminal pins are received within the plurality of vias.

### BRIEF DESCRIPTION OF THE SEVERAL VIEWS OF THE DRAWING

The present invention will now be described, by way of example with reference to the accompanying drawings, in which:

FIG. 1 is a cross section side view of a printed circuit board (PCB) assembly according to the prior art;

FIG. 2 is a top view of a PCB substrate according to the prior art;

FIG. 3 is a bottom view of a printed circuit board (PCB) assembly according to the prior art;

FIG. 4 is a top view of a PCB substrate according to one embodiment;

FIG. 5 is a cross section side view of a printed circuit board (PCB) assembly according to one embodiment; and

FIG. 6 is a bottom view of a printed circuit board (PCB) assembly according to one embodiment.

### DETAILED DESCRIPTION OF THE INVENTION

Presented herein is a non-limiting example of a printed circuit board (PCB) assembly having a PCB that has a plurality of plated through mounting holes or “vias” aligned along a common axis that are configured to receive an electrical device having multiple terminal pins. One of the vias may be formed by drilling a substantially circular hole in the PCB while the other vias may be formed by milling elongated oval holes in the PCB. The circular via is sized so that the terminal pin received within it is held in place by a press fit while the other vias provide contact with only two sides of the terminal pins. If the electrical device has three or more terminal pins, the circular via is located centrally and all of the other vias are elongated or “slotted”. For simplicity, conductive traces on the surface of the PCB substrate that connect the vias to other electrical components are not shown in FIGS. 4-6.

The PCB assembly may use circuit board substrates that are formed of epoxy or polyimide resins. The resin may be reinforced with a woven glass cloth or other matrix such as chopped fibers. Substrates formed of such materials are typically referred to as FR-4 or G-10 type circuit boards. The circuit board substrate may alternatively be constructed of ceramic or rigid polymer materials. This listing of acceptable substrate materials is not exhaustive and other materials may also be used successfully. A layer of conductive material, such as a copper based material is electroplated on at least one major surface of the circuit board substrate. The layer of conductive material is then formed to create the conductive traces and conductive pads typically by using a chemical etching process.

A via consists of two pads in corresponding positions on different layers of the PCB substrate that are electrically connected by a hole through the board. The hole is made conductive by electroplating. The pad on one both sides of the PCB is connected to a conductive trace formed on a surface of the PCB. The conductive traces interconnect the electrical component to other electrical components on the PCB. The materials and manufacturing techniques used to the form PCBs and vias are well known to those skilled in the art.

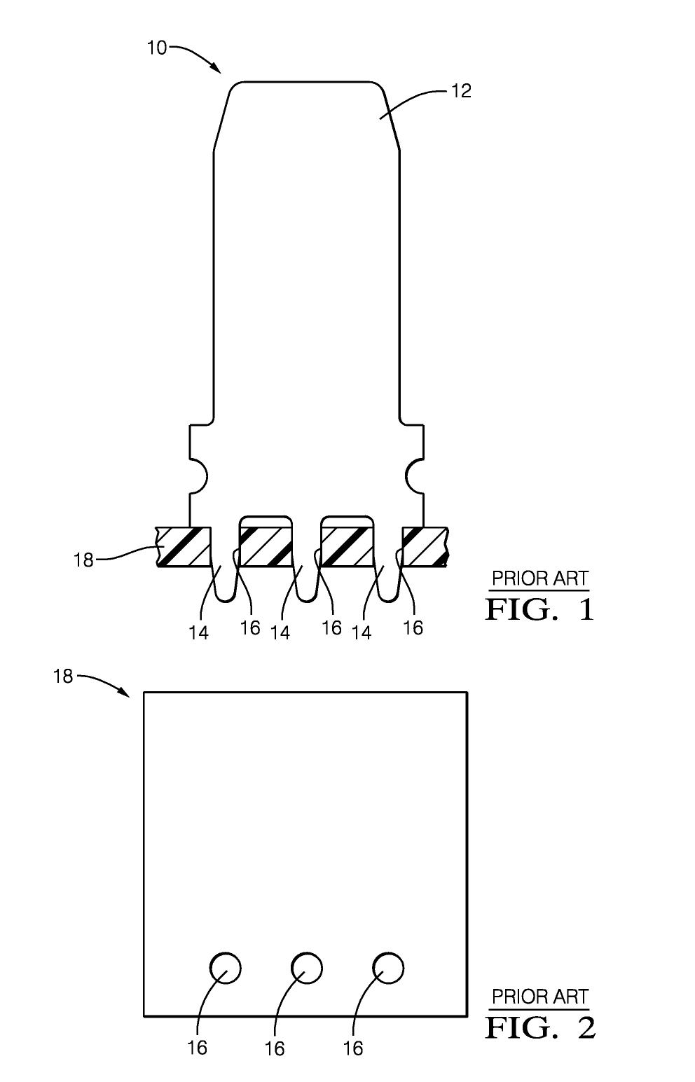

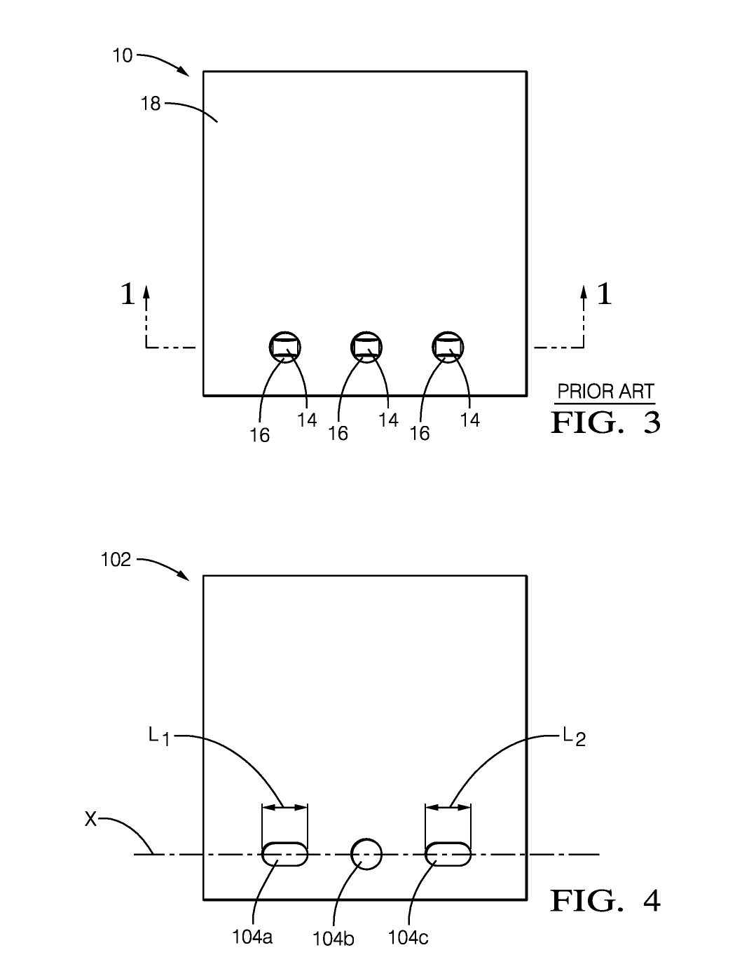

FIG. 1 illustrates a non-limiting example of a PCB substrate 102 used in a PCB assembly 100. The PCB substrate 102 defines a plurality of vias 104a-c that are aligned along a common axis X. A first via 104b defines a circular shape while a second via 104a and a third via 104c each define an oval shape that is elongate along the common axis X. The first via 104b is located centrally to the second and third vias 104a, 104c. According to the illustrated embodiment, he second via 104a and the third via 104c are equidistant from the first via 104b and a length L₁ of the second via 104a along the common axis X is equal to a length L₂ of the third via 104c along the common axis X.

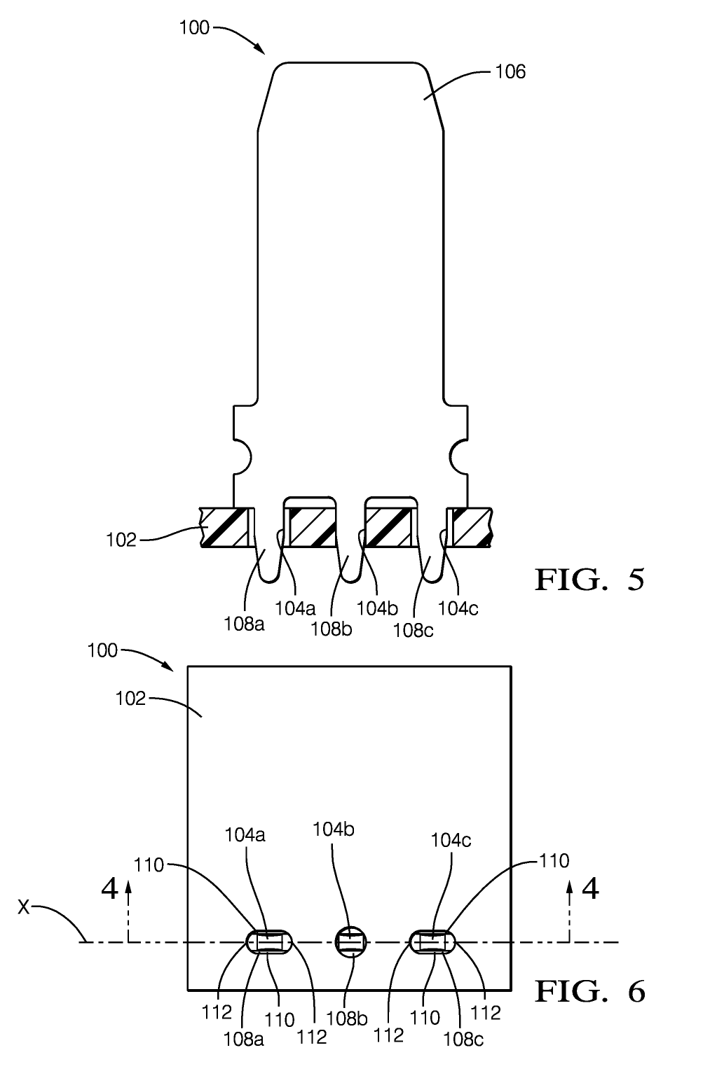

FIG. 5 illustrates an example of a PCB assembly 100 including an electrical component 106, in this example a male blade terminal 106, having a plurality of terminal pins 108a-c that are aligned along the common axis X. The plurality of terminal pins 108a-c are received within the plurality of vias 104a-104c of the PCB substrate 102 and are electrically and mechanically attached to the vias by a solder joint (not shown).

As can be seen in FIG. 6, the central terminal pin 108b is received in the circular first via 104b while the distal terminal pins 108a, 108c are received in the second and third vias 104a, 104c. Only the central terminal pin 108b is interference fit to the first via 104b providing positive positioning of the on the PCB substrate 102. The distal terminal pins 108a, 108c may make contact with the flat edges 110 of the second and third vias 104a, 104c but do not make contact with the rounded ends 112 of the second and third vias 104a, 104c, thus providing longitudinal positional tolerance of the distal terminal pins 108a, 108c in the second and third vias 104a, 104c along the X axis.

While the illustrated embodiment of the PCB assembly includes an electrical components with three terminal pins, other embodiments of the invention may be envisioned wherein the electrical component has only two terminal pins or more than three terminal pins aligned along a common axis. Likewise, alternative embodiments of the PCB substrate may be envisioned wherein the PCB defines one circular and one elongate via or more than three vias aligned along a common axis wherein one of the vias has a circular shape and the other vias have an oval or slotted shape that is elongate along the common axis. The circular via does not necessarily need to be located central to the other vias.

Accordingly a PCB assembly 100 is provided. The PCB assembly 100 has a PCB substrate 102 that includes elongate vias 104a, 104c that allow for component dimensional tolerance between the vias 104a, 104c and the terminal pins 108a, 108c of electrical components 106. This provides the benefits of reduced production scrap, a more reliable electrical connection, and reduced warranty costs for the PCB assembly 100 due to reduced operation failures.

While this invention has been described in terms of the preferred embodiments thereof, it is not intended to be so limited, but rather only to the extent set forth in the claims that follow. Moreover, the use of the terms first, second, etc. does not denote any order of importance, but rather the terms first, second, etc. are used to distinguish one element from another. Furthermore, the use of the terms a, an, etc. do not denote a limitation of quantity, but rather denote the presence of at least one of the referenced items.

We claim:

1. A printed circuit board configured to receive an electrical component having a plurality of terminal pins aligned along a first axis, comprising:
a circuit board substrate defining a plurality of vias aligned along a second axis and configured to receive the plurality of terminal pins, wherein a first via of the plurality of vias defines a circular shape and a second via defines an elongate oval shape along the second axis, and wherein the first axis is correspondent with the second axis when the plurality of terminal pins are receded within the plurality of vias.

2. The printed circuit board according to claim 1, wherein the first via of the plurality of vias is located central to the second via and a third via of the plurality of vias, wherein the third via defines an elongate oval shape along the second axis.

3. The printed circuit board according to claim 2, wherein the second via and the third via are equidistant from the first via.

4. The printed circuit board according to claim 3, wherein a length of the second via along the second axis is equal to a length of the third via along the second axis.

5. A printed circuit board assembly, comprising:
a circuit board substrate defining a plurality of vias aligned along a common axis, wherein a first via of the plurality of vias defines a circular shape and a second via defines an elongate oval shape along the common axis; and
an electrical component having a plurality of terminal pins aligned along the common axis, said plurality of terminal pins received within said plurality of vias.

6. The printed circuit board assembly according to claim 5, wherein the first via of the plurality of vias is located central to the second via and a third via of the plurality of vias, wherein the third via defines an elongate oval shape along the common axis.

7. The printed circuit board assembly according to claim 6, wherein the second via and the third via are equidistant from the first via.

8. The printed circuit board assembly according to claim 7, wherein a length of the second via along the common axis is equal to a length of the third via along the common axis.
